(19) United States
(12) Patent Application Publication
(10) Pub. No.: US 2005/0139971 A1
(43) Pub. Date: Jun. 30, 2005

(54) Continuous molding method and molding apparatus for surface fastener

(76) Inventor: Tsuyoshi Minato, Toyama-ken (JP)

Correspondence Address: Michael S. Leonard;Everest Intellectual Property Law Group, P.O. Box 708, Northbrook, IL, 60065, US

(21) Appl. No.: 11/021,010

(22) Filed: Dec. 23, 2004

(30) Foreign Application Priority Data
Dec. 25, 2003 (JP) 2003-429777

(51) Int. Cl. H01L 23/495

(52) U.S. Cl. 257/676

(57) ABSTRACT

The invention provides a molding method and molding apparatus, effective and cheap, for a surface fastener to be directly/indirectly bonded with/fit to an mounting object, capable of increasing the bonding strength or friction force regardless of the configuration of a bonding surface, wherein molten resin is discharged continuously from a resin extruding port of an extrusion die to a peripheral surface of a die wheel having hook piece forming cavities therein for forming hook pieces in the hook piece forming cavities while forming a flat base member at a gap between the extrusion die and the die wheel, the rear surface of a surface fastener without engaging elements is cooled by feeding refrigerant through a refrigerant passage formed in the extrusion die below the resin extruding port, surface sinks are formed in the entire rear surface for increasing bonding area, thereby increasing bonding strength and friction force.

### BACKGROUND OF THE INVENTION

1. Field of the Invention

The present invention relates to a continuous molding method for a surface fastener for integrally molding a number of engaging elements erected on a surface of a flat base member at the same time when the flat base member is formed by continuous extrusion with thermoplastic resin, and a molding apparatus therefor.

2. Description of the Related Art

According to a conventionally known method of manufacturing a molded surface fastener, a thermoplastic resin material in a molten state is extruded continuously from an extrusion die to a peripheral surface of a die wheel having a number of engaging element forming cavities in its peripheral surface and rotating in a single direction so as to mold a flat base member between the peripheral surface of the die wheel and the front surface of the extrusion die at the same time of forming engaging elements by the engaging element forming cavities on the rotating die wheel. On the other hand, generally, adhesive agent such as pressure sensitive adhesive agent is applied on a rear surface of the surface fastener to mount this surface fastener on an objective product such as a disposable diaper.

An opposing surface of the extrusion die to the die wheel is usually formed in a smooth circular face along the peripheral surface of the die wheel and as a consequence, a surface (rear surface) of the flat base member formed continuously between this extrusion die and the die wheel on a side in which no engaging elements are formed also has a high smoothness. In case where this plane-like fastener is integrated with an objective product by applying the aforementioned adhesive agent to such a smooth surface, adhesive force between the smooth surface of the flat base member and the adhesive agent is much lower than the adhesive force to a rough surface or an uneven surface. To form such a rough surface or uneven surface, generally, a die roller having unevenness on its peripheral surface such as an emboss roller is used, the emboss roller embossing an exposed surface of the flat base member of a surface fastener carried by the peripheral surface of the die wheel at downstream side from the extrusion die.

Further, this kind of molded surface fastener is sometimes used as a joining member for joining a sheet-like member such as a curtain or a wire net for a door to various types of frames. This joining member comprises a long molded surface fastener made of synthetic resin material and plural engaging rows formed integrally with the molded surface fastener in parallel and continuously in a length direction on a rear surface of a flat base member of the surface fastener as disclosed in for example, U.S. Pat. No. 5,800,760. A number of hook pieces which are engaging elements are formed integrally on a front surface of the flat base member such that they stand upright. Each of the engaging rows is composed of a continuous protruded piece having a substantially T-shaped section, which is to be engaged in an engaging groove having a substantially T shaped section formed integrally in one surface of the frame. After the protruded piece of the joining member is fit to the engaging groove formed in the frame, a female engaging member having, for example, a number of loop pieces provided on an edge of the sheet-like member is brought into a contact with an engaging face composed of a number of hook pieces formed on the surface of the joining member so as to join the frame to the sheet-like member.

As disclosed in, for example, U.S. Pat. No. 5,945,193, a surface fastener is buried and integrally formed, with a number of engaging elements exposed, when a cushion material of automobile, office chair and the like is molded in. In a flat base member of the surface fastener, there is buried a porous spread metallic sheet extending in a molding direction. Further, it has been disclosed that a number of anchor pieces having the same shape as a number of hook pieces or engaging elements formed on a front surface of the flat base member are integrally and continuously formed on a rear surface of the flat base member at the same time when the surface fastener is molded. An example of a method of molding the surface fastener is shown in FIG. 8 of its specification. According to an explanation of this figure, this molding apparatus uses a cross head die having two resin extruding ports disposed up and down, and first and second rollers are disposed up and down with the same gap as the thickness of a flat base member opposing the same die head. A guide passage of the porous spread metallic sheet is formed between the two resin extruding ports disposed up and down. A number of hook-like cavities are formed in peripheral surfaces of the first and second rollers.

The first and second rollers are driven synchronously and rotated in opposite directions to each other. On the other hand, molten resin is extruded from the upper and lower resin extruding ports in the cross head die with a predetermined width and at the same time, a porous spread metallic sheet is supplied in between the upper and lower extruded resin at the same speed as an extrusion speed. The extruded molten resin sandwiching the porous spread metallic sheet reaches between the first and second rollers together with the porous spread metallic sheet and is introduced into a gap between the first and second rollers. The introduced porous spread metallic sheet is spread, and the engaging elements and the anchor pieces having the same shape are formed on the front and rear surfaces through cavities formed in the peripheral surfaces of the first and second rollers with part of the upper and lower molten resin. In this while, a flat base member is formed integrally and continuously with the spread metallic sheet buried therein.

When a core material for an automobile seat is formed using an elastomer resin material such as polyurethane, an obtained molded surface fastener is used to be buried integrally in a predetermined portion of the surface. If speaking of an example of its molding method briefly, a molded surface fastener of a required length obtained in the above-described manner is placed and fixed in part of a bottom surface of a cavity of a formation mold for the seat core material with the surface of the molded surface fastener having the anchor pieces facing upward and then, the elastomer resin material is poured therein so as to form a foamed seat core material. At this time, in order to determine a placing position of the molded surface fastener and then place and fix the same fastener, a magnet or the like is buried inside the mold near the bottom surface on which the molded surface fastener is to be placed, preliminarily. On the other hand, since the aforementioned porous spread metallic sheet made of a magnetic material is buried in the flat base member of the surface fastener, if the same surface fastener is placed on the bottom surface of the cavity of the mold, the surface fastener is attracted by magnetic force so that it is fixed at a predetermined position.

Although bonding strength between the molded surface fastener and the foamed elastomer resin material is usually sufficient due to an existence of the surface with the anchor pieces, sometimes, a higher bonding strength is required. As means for intensifying the bonding strength with other structure than the anchor pieces, an bonding area can be increased by embossing a surface on a bonding side of the flat base member, as described previously.

However, mechanical embossing of the surface of the flat base member of the aforementioned molded surface fastener at one time in a base member formation region with the rotation roller is impossible as long as the continuous molding methods as mentioned in U.S. Pat. Nos. 5,800,760 and 5,945,193 are adopted. Especially, if the anchor pieces composed of inverted-T shaped engaging row or hook pieces are formed on a surface opposite to an engaging element formation surface as described in the aforementioned U.S. patens, not only the embossing but also any mechanical processing is impossible. Even if the surface of the base member opposite to the engaging element formation face of the molded surface fastener is smooth, it is necessary to provide with an emboss roller separately at downstream side from the molding roller or in an opposing condition to the peripheral surface of the molding roller, because the embossing in the base member formation region is impossible as described above, as long as the continuous molding method is adopted. An installation of this emboss roller leads to increase of drive system elements, which is desired to be avoided for an economic reason if possible.

### SUMMARY OF THE INVENTION

Accordingly, an object of the present invention is to solve the above-described problems and then, provide a molding method and molding apparatus, effective and cheap, for a molded surface fastener required to be directly or indirectly bonded with or fit to an mounting object, capable of increasing a bonding strength or a friction force regardless of a configuration of a bonding surface.

To achieve the above-described object, according to an aspect of the present invention, there is provided a continuous molding method for a surface fastener made of synthetic resin material, the method comprising steps of: rotating a die wheel having a number of engaging element forming cavities in a peripheral surface thereof in a single direction; extruding continuously molten resin of a predetermined width from a resin extruding port of an extrusion die toward a gap between the peripheral surface of the die wheel which is rotating and a front surface of the extrusion die at a predetermined resin pressure so as to apply part of the molten resin into engaging element forming cavities to form the engaging elements while forming continuously a flat base member having a thickness similar to the gap between the peripheral surface of the die wheel and the extrusion die with an excess of the molten resin; and feeding refrigerant through a refrigerant passage disposed inside the extrusion die located downstream in a rotation direction of the die wheel from the resin extruding port so as to cool the surface of the flat base member without the engaging elements for forming fine unevenness in the surface. As the refrigerant, preferably, air or water is used.

The above-mentioned method is effectively executed by a continuous molding apparatus of the invention, that is, the continuous molding apparatus for a surface fastener made of a synthetic resin material, the apparatus comprising: a die wheel having a number of engaging element forming cavities in a peripheral surface thereof and rotating in a single direction; and an extrusion die disposed so as to oppose to the die wheel with a required gap with respect to the peripheral surface of the die wheel and having an extruding port with a predetermined width for molten resin in part of an opposing face, wherein a refrigerant passage extending across a width direction is provided inside the extrusion die located downstream in a rotation direction of the die wheel from the extruding port.

Preferably, the continuous molding apparatus further comprises one or more groove portions provided in an opposing face to the die wheel and downstream from the extruding port of the extrusion die in the rotation direction of the die wheel so as to extend in the rotation direction of the die wheel. Preferably, the section of each of the groove portions is triangular, U shaped or inverted-T shaped. However, a sectional shape of the groove portion is not limited to these sections, but, it is permissible to adopt for example, W shaped section.

According to the present invention, by forming the refrigerant passage inside the extrusion die located downstream in the rotation direction of the die wheel from the resin extruding port in the extrusion die and then, feeding refrigerant through the refrigerant passage, a portion near an opposing face of the extrusion die to the peripheral surface of the die wheel, located downstream from the resin extruding port, is cooled by the refrigerant. The molten resin extruded from the resin extruding port is applied into engaging element forming cavities formed in the peripheral surface of the die wheel so as to form the engaging elements and at the same time, a flat base member is formed continuously integrally with the engaging elements between the peripheral surface of the die wheel and the extrusion die. This molded surface fastener is carried by about ⅓ of the peripheral surface of the die wheel and transported in the rotation direction by a rotation of the die wheel.

The flat member is formed between the extrusion die and the die wheel with part of the molten resin extruded from the resin extruding port in connection with the rotation of the die wheel, and a rear surface of the flat base member having no engaging elements is formed continuously by the front surface of the extrusion die. During a formation of this rear surface, the rear surface is cooled aggressively by the refrigerant flowing through the extrusion die. At this time, the surface of the flat base member for supporting proximal ends of the engaging elements of the flat base member is formed at the same time when the engaging elements are formed by the peripheral surface of the die wheel. Although usually, cooling water flows through the inside of the die wheel so as to cool the flat base member from a side in which the engaging elements are formed, the surface (rear surface) of the flat base member on a side of the extrusion die is under high temperatures. That is, according to the method of the present invention, in an initial period of molding of the surface fastener, the side in which the engaging elements are formed is cooled aggressively and the rear surface on an opposite side is also cooled aggressively. As a result of this cooling, a number of fine unevenness are formed in the same rear surface.

The reason is that surface sinks are generated in portions of the flat base member corresponding to the portions of the front surface in which the engaging elements are formed as a result of an aggressive cooling of the rear surface of the flat base member.

According to the method of the present invention, by forming the fine unevenness in the rear surface of the flat base member of the molded surface fastener, a bonding area increases, so that a bonding strength with an adhesive agent or a foamed resin is intensified remarkably. Because a clear uneven surface can be generated by using air or water which is cheap and easy to obtain as the refrigerant flowing through the extrusion die, it is not necessary to use any special refrigerant.

As described above, the rear surface of the flat base member can be cooled aggressively in the initial period of molding of the surface fastener with a simple structure in which a refrigerant passage extending in the width direction is formed inside the extrusion die located downstream in the rotation direction of the die wheel from the extruding port in the extrusion die so as to feed the refrigerant, and a number of fine unevenness is formed in the rear surface of the flat base member by cooling. Therefore, it is not necessary to provide any mechanical unevenness forming means such as an emboss roller.

The fact that the fine unevenness can be formed without any special embossing procedure means that engaging rows each having a T-shaped section as disclosed in U.S. Pat. No. 5,800,760, or large grooves each having a triangular section or U-shaped section are formed continuously on the rear surface of the flat base member at the same time when the surface fastener is molded, while fine unevenness can be formed on the surface thereof.

In the molding apparatus of the present invention, one or more grooves extending in the rotation direction of the die wheel whose ends are open to the extruding port are formed in an opposing face in the rotation direction of the die wheel downstream from the extruding port in the extrusion die outside of the refrigerant passage. The section of this groove is triangular, U-shaped or inverted T shaped, and a large uneven surface extending continuously in a length direction and having a zigzag shaped section can be formed on the rear surface of the flat base member by this groove portion. A bonding performance and friction with adhesive agent or elastomer foamed resin can be increased by this continuous uneven surface.

### BRIEF DESCRIPTION OF THE DRAWING

FIG. 1 is a longitudinal sectional view of major components showing schematically a manufacturing apparatus and manufacturing procedure for a surface fastener according to a first embodiment of the present invention;

FIG. 2 is an enlarged perspective view of part of a surface fastener manufactured according to the first embodiment as seen from its back side;

FIG. 3 is a longitudinal sectional view of major components showing schematically a manufacturing apparatus and manufacturing procedure for a surface fastener according to a second embodiment of the present invention;

FIG. 4 is an enlarged sectional view taken along the line IV-IV in FIG. 3;

FIG. 5 is an enlarged perspective view of part of a surface fastener with grooves manufactured according to the second embodiment as seen from its back side;

FIG. 6 is a sectional view of a manufacturing apparatus for a surface fastener with engaging rows according to a third embodiment of the present invention, corresponding to FIG. 4; and

FIG. 7 is a perspective view of the surface fastener with engaging rows manufactured according to the third embodiment as seen from its back side.

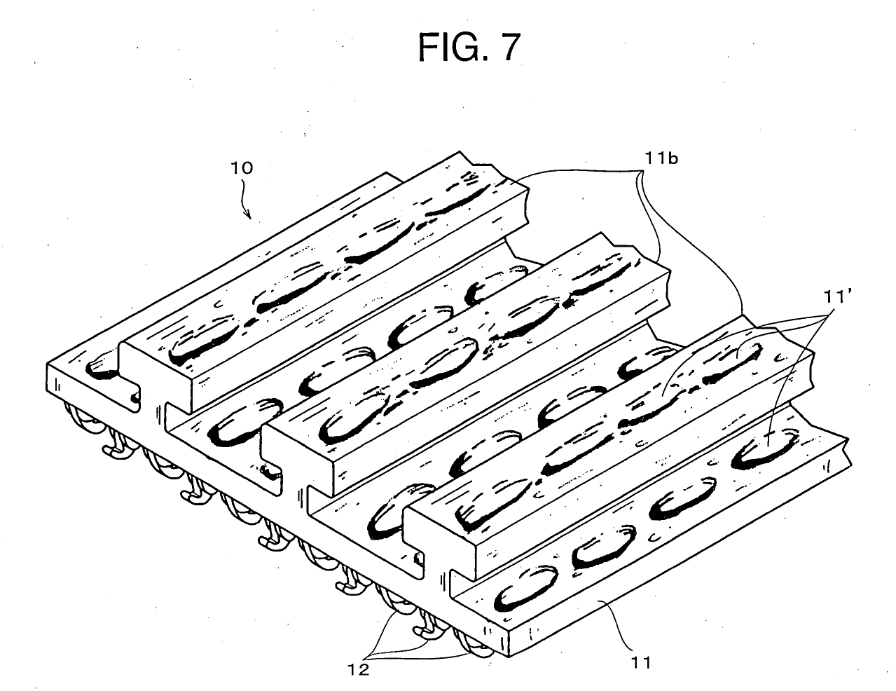

### DESCRIPTION OF THE PREFERRED EMBODIMENTS

Hereinafter, embodiments of the present invention will be described with reference to the accompanying drawings.

### First Embodiment

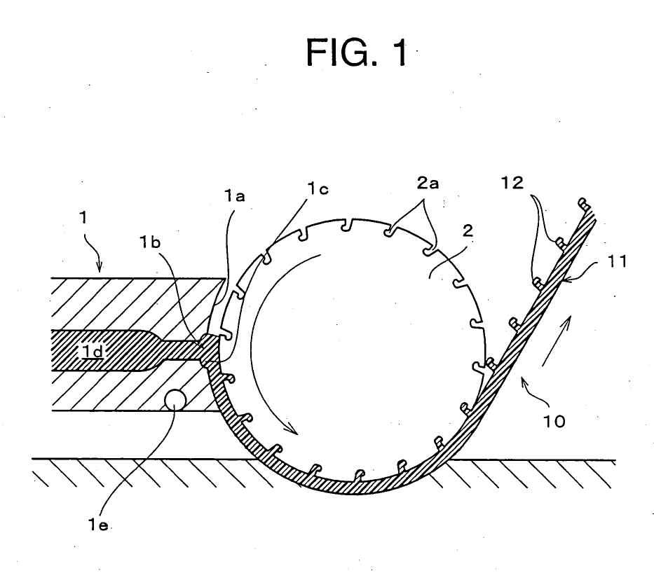

FIG. 1 is a longitudinal sectional view showing a continuous molding apparatus and molding procedure for a molded surface fastener according to a first embodiment of the present invention. Although this embodiment adopts a hook piece as an engaging element formed on a surface of a base member, this embodiment is not restricted to this configuration and various types such as mushroom type or double leaves type may be adopted. The molded surface fastener of this embodiment is an ordinary surface fastener and no special notch or engaging row is formed on a rear surface of a flat base member having no engaging elements.

In this figure, reference numeral 1 denotes a (continuous) extrusion die, and a front end of the extrusion die 1 is formed as a circular face 1a having such a curvature which allows a predetermined gap to be formed with respect to a round peripheral surface of a die wheel 2 described later. This extrusion die 1 is constituted of a T type die, and as shown in the same figure, a substantially rectangular piped, concave molten resin reservoir 1c is formed in a center of the circular face 1a. A resin extruding port 1b for extruding molten resin for forming a flat base member 11 and hook pieces 12 of a surface fastener 10 is open in the molten resin reservoir 1c. According to this embodiment, the extrusion die 1 has a molten resin passage 1d in the center, and molten resin extruded from an extruder (not shown) is extruded into the molten resin passage 1d continuously by a specified amount through a gear pump (not shown). Then, a molten resin material having a predetermined width and thickness is extruded continuously toward the peripheral surface of the die wheel 2 through the molten resin reservoir 1c from the resin extruding port 1b at the front end of the molten resin passage 1d.

Further, according to this embodiment, a refrigerant passage 1e extending linearly in a width direction is formed inside the extrusion die 1 near a bottom surface of the extrusion die 1 below the resin extruding port 1b. An introduction pipe and a discharge pipe (not shown) are connected to right and left open ends of this refrigerant passage 1e so as to feed the refrigerant into the refrigerant passage 1e. As the refrigerant of this embodiment, air is used and external air is introduced directly from outside with a fan (not shown). By feeding this refrigerant, the circular face 1a below the resin extruding port 1b opposing the peripheral surface of the die wheel 2 is maintained at low temperatures.

The peripheral surface of the die wheel 2 is disposed so that its axial line is in parallel to the resin extruding port 1b with a predetermined gap with respect to the circular face 1a of the extruding die 1. According to the indicated example, a number of hook piece forming cavities which are engagement element forming cavities 2a of the invention are formed in the peripheral surface of the die wheel 2 (hereinafter each of the hook piece forming cavities are referred to as a hook piece forming cavity 2a). Because a structure of this die wheel 2 is substantially equal to a structure disclosed in, for example, U.S. Pat. No. 4,775,310, the structure will be described briefly. An interior of the die wheel 2 is constructed in the form of a hallow drum containing a water cooling jacket (not shown), a number of ring-like sheets are overlaid and fixed in a central portion along an axial line, and a number of hook piece forming cavities 2a are cut out at a periphery of rear and front surfaces of each of the ring-like sheets in such a manner that proximal ends of hook pieces are open to the peripheral surface. The die wheel 2 having such a structure is rotated in a direction indicated with an arrow by a well known drive unit (not shown). A pair of upper and lower catching rolls (not shown), which rotates synchronously with a rotation speed of the die wheel 2 is provided ahead of the die wheel 2.

Molten resin extruded from an extruder (not shown) is reserved by a specified amount in the molten resin reservoir 1c through the gear pump (not shown) and discharged continuously into a gap formed with respect to the peripheral surface of the die wheel 2 rotating in a single direction. Part of this discharged molten resin forms continuously the flat base member 11 of the surface fastener 10 between the peripheral surface of the die wheel 2 and the circular face 1a of the extruding die 1. At this time, excess portion of the molten resin is applied into the hook piece forming cavities 2a open to the peripheral surface of the die wheel 2 and hence the hook pieces 12, which are engaging element of the surface fastener 10, are formed integrally on one surface of the flat base member 11.

A hook piece forming side of the surface fastener 10 still in a molten state after the molding is cooled by cooling means such as a water cooling jacket disposed inside the die wheel 2, carried by the die wheel 2 and transported downstream by a rotation of the die wheel 2. At this time, because usually the extrusion die 1 has no cooling means for cooling the circular face 1a, a rear surface side of the molded surface fastener 10 in which no engaging elements 12 are formed is placed under high temperatures until the surface fastener 10 passes the extrusion die 1. After the surface fastener 10 passes the extrusion die 1, it is introduced into a water bath with part of the die wheel 2 so that it is entirely cooled and hardened.

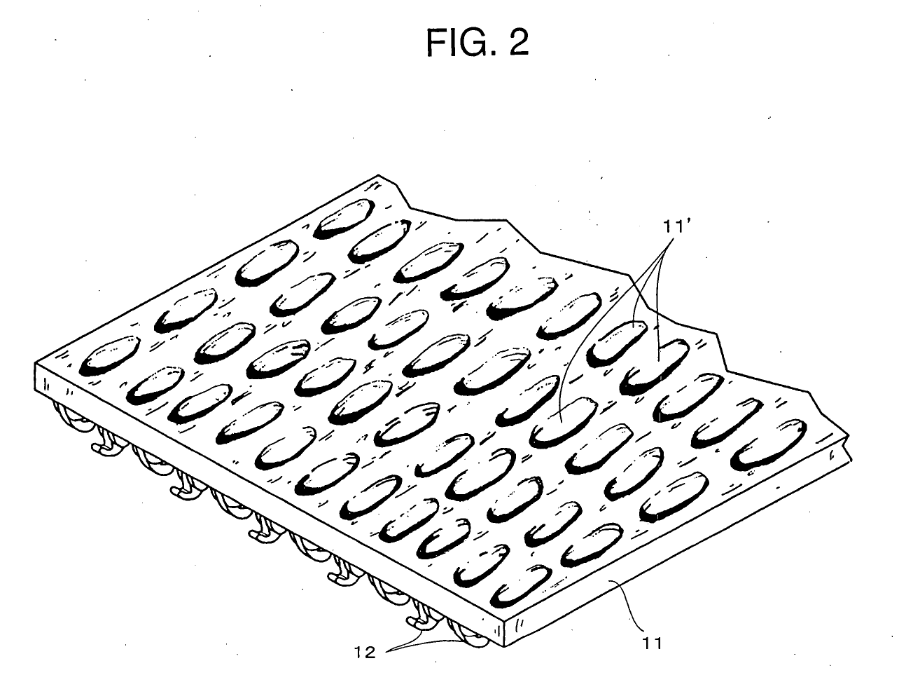

However, according to this embodiment, the refrigerant passage 1e is formed inside the extrusion die 1 below the molten resin reservoir 1c of the extrusion die 1 as described above, and cooling air flows through the refrigerant passage 1e. As a consequence, an extrusion die portion around the refrigerant passage is maintained at temperatures lower than the melting point of the molten resin by about 20 to 50° C. As a result, the rear surface side of the surface fastener 10 carried by and in contact with the circular face 1a located below the resin extruding port 1b together with the die wheel 2 is cooled aggressively. Because the hook pieces 12 are formed on the surface of the flat base member 11 on the side of the die wheel 2, the heat capacity of a portion of the flat base member 11 corresponding to the hook pieces 12 increases, thereby delaying the hardening. Upon hardening, local surface sinks are generated in the rear surface of the flat base member 11. Due to the generation of the surface sinks 11′, a number of uneven faces having fine unevenness are formed in the rear surface of the surface fastener 10 after production as shown in FIG. 2. The bonding area on the rear surface of the surface fastener is increased largely by this uneven surface, and with such an increase, the bonding strength with the adhesive agent or a fusion strength with a fusion material increases remarkably. In the meantime, it is permissible to use water or oil instead of air as the refrigerant to be fed through the refrigerant passage 1e.

### Second Embodiment

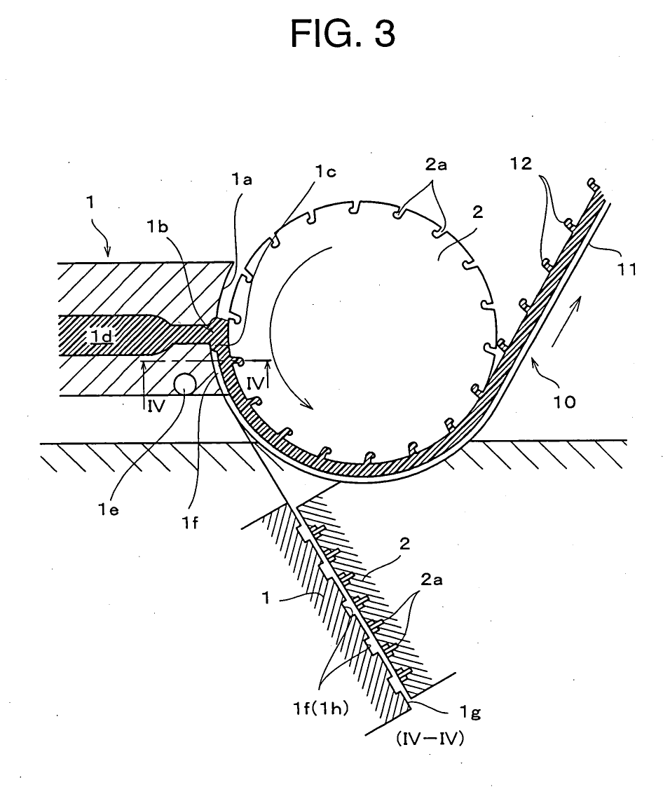

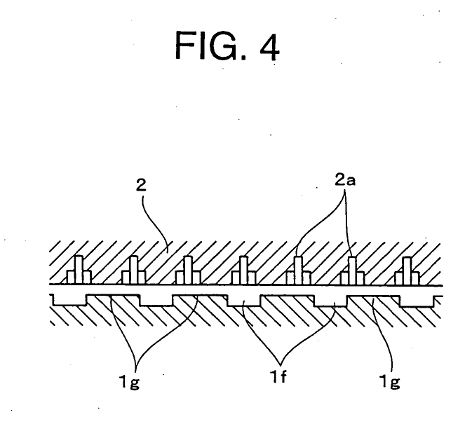

Next, a second embodiment of the present invention will be described. FIG. 3 shows a continuous molding apparatus for a molded surface fastener and its molding procedure according to the second embodiment of the present invention. FIG. 4 is a sectional view taken along a line IV-IV in FIG. 3. In these figures, what is largely different from the first embodiment exists in a shape of the circular face 1a below the resin extruding port 1b in the extrusion die 1. The other configuration is not substantially different from the first embodiment. Hence, in the following description, different portions from the first embodiment will be stated specifically while the same components will be explained briefly.

According to this embodiment, as shown in FIG. 4, plural concave groove forming paths 1f are formed in parallel in the circular face 1a located below the molten resin reservoir 1c formed on the front surface of the extrusion die 1 such that they extend along a circularity. Each of the concave groove forming path 1f of this embodiment is formed between protrusions 1g having a substantially rectangular section as indicated partially by a cross section in FIG. 4. An end of the concave groove forming path 1f communicates with a bottom end of the resin extruding port 1b, and the other end extends downstream in the rotation direction of the die wheel 2 and is open to outside.

Part of the molten resin discharged from the resin extruding port 1b is introduced into the concave groove forming path 1f, so that a groove portion 11a having a substantially U-shaped section is formed continuously on the rear surface of the flat base member 11 of the surface fastener 10 by the protrusions 1g having a substantially rectangular section for defining the concave groove forming path 1f. In the meantime, a sectional shape of the concave groove forming path 1f is not restricted to the rectangular shape, but, may be, for example, of V shape, W shape or C shape as long as the sectional shape can be formed continuously.

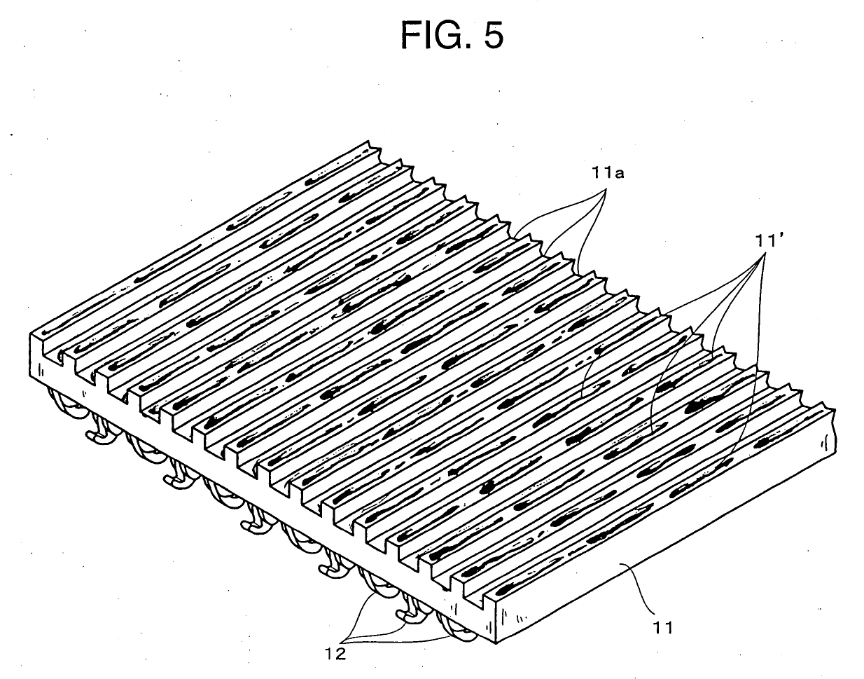

While the groove portion 11a is formed as shown in FIG. 5, the rear surface of the flat base member 11 is cooled by refrigerant flowing through the refrigerant passage 1e formed inside the extrusion die 1 so as to generate the local surface sinks 11′, thereby producing a fine uneven surface on the rear surface. At this time, the surface sinks 11′ are generated not only in the groove portions 11a but also equally in its thick portions. Particularly, in case where it is intended to form relatively large groove portions 11a in the rear surface of the flat base member 11 like this embodiment, it is impossible to form the uneven surface equally on the entire rear surface by the conventionally used embossing treatment. However, this embodiment enables the fine unevenness to be formed equally on the entire rear surface of the flat base member 11 including the groove portion 11a. Thus, a wider bonding or fusion area is secured as compared with a case where mere groove portions are formed. As a consequence, not only the high bonding strength with the adhesive agent is secured, but also, for example, in case where an elastomer resin foamed body is molded, it is integrated with a high joining strength.

### Third Embodiment

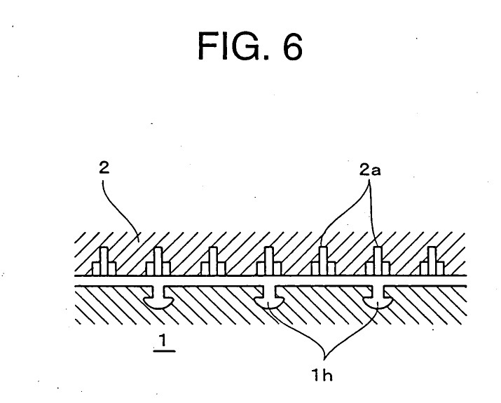

FIG. 6 schematically shows a section of a continuous molding portion of a molded surface fastener according to a third embodiment of the present invention. This embodiment concerns a continuous molding apparatus for a molded surface fastener with an engaging row which is interposed between a mounting frame and a sheet material in order to attach the sheet material such as a curtain to the mounting frame, and its molding procedure.

Although this embodiment is different from the second embodiment in terms of dimension, the structure of the major components and its molding procedure are not largely different from the first and second embodiments. What is different from the first and second embodiments is that one or more engaging row forming paths 1h having an inverted-T shaped section one end of which communicates with the resin extruding port 1b while the other end is open to an end in the rotation direction of the die wheel of the circular face 1a are formed in the center in the width direction of the circular face 1a of the extrusion die 1. Hence, according to this embodiment, one or more engaging rows 11b are formed integrally by introducing part of the molten resin to the rear surface of the flat base member 11 through the engaging row forming paths 1h communicating with the molten resin reservoir 1c at the same time when the flat base member 11 is molded.

According to this embodiment as well, like the first and second embodiments, the engaging element forming side of the surface fastener 10 formed into a shape of the surface fastener with engaging rows along the peripheral surface of the die wheel 2 is cooled from the inside of the die wheel 2 while it rotates along substantially ⅓ of the peripheral surface of the die wheel 2 and hardened gradually. On the other hand, the rear surface side of the surface fastener 10 in which no engaging elements 12 are formed is cooled through the extrusion die 1 by refrigerant flowing through the refrigerant passage 1e formed inside the extrusion die 1 like the first and second embodiments. Due to this cooling, a fine uneven surface having local surface sinks 11′ is formed not only on the rear surface of the flat base member 11, but also throughout the entire surface of the side in which the engaging rows 11b each having the T-shaped section are formed like the second embodiment. Due to the formation of this fine uneven surface, when the engaging row 11b is inserted into a frame member (not shown) composed of a curtain rail having a C-shaped section such that the engaging element forming face of the surface fastener 10 is exposed outside, a friction coefficient of the entire surface of the engaging row 11b increases, so that it does not slip out of the frame member easily but it is fit therein securely.

1. A continuous molding method for a surface fastener made of synthetic resin material, comprising steps of:
rotating a die wheel having a number of engaging element forming cavities in a peripheral surface thereof in a single direction,
continuously extruding molten resin of a predetermined width from a resin extruding port of an extrusion die toward a gap between the peripheral surface of the die wheel which is rotating and a front surface of the extrusion die at a required resin pressure so as to apply part of the molten resin into engaging element forming cavities to form engaging elements while forming continuously a flat base member having a thickness similar to the gap between the peripheral surface of the die wheel and the extrusion die with an excess of the molten resin, and
feeding refrigerant through a refrigerant passage disposed inside the extrusion die located downstream in a rotation direction of the die wheel from the resin extruding port so as to cool a surface of the flat base member without the engaging elements for forming unevenness in the surface.

2. The continuous molding method for a surface fastener according to claim 1, wherein the refrigerant is air or water.

3. A continuous molding apparatus for a surface fastener made of synthetic resin material, comprising:
a die wheel having a number of engaging element forming cavities in a peripheral surface thereof and rotating in a single direction, and
an extrusion die disposed so as to oppose to the die wheel with a required gap with respect to the peripheral surface of the die wheel and having an extruding port with a predetermined width for molten resin in part of an opposing face, wherein
a refrigerant passage extending across a width direction is provided inside the extrusion die located downstream in a rotation direction of the die wheel from the extruding port.

4. The continuous molding apparatus for a surface fastener according to claim 3, comprising plural groove portions extending in parallel in the rotation direction of the die wheel in an opposing face which is downstream in the rotation direction of the die wheel from the extruding port of the extrusion die.

5. The continuous molding apparatus for a surface fastener according to claim 3 or 4, wherein a cross section of each of the groove portions is V shaped or U shaped.

6. The continuous molding apparatus for a surface fastener according to claim 3 or 4, wherein a cross section of each of the groove portions is inverted-T shaped.
